(19) United States
(12) Patent Application Publication
(10) Pub. No.: US 2026/0305285 A1
(43) Pub. Date: Oct. 1, 2026

(54) SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Chang-An Chen, Hsinchu (TW); Chia-Shen Cheng, Hsinchu County (TW); Ying-Jui Huang, Hsinchu County (TW); Hao-Jan Pei, Hsinchu (TW); Hsiu-Jen Lin, Hsinchu County (TW)

(73) Assignee: Taiwan Semiconductor Manufacturing Company, Ltd., Hsinchu (TW)

(21) Appl. No.: 19/091,859

(22) Filed: Mar. 27, 2025

(51) Int. Cl. H01L 23/00; H01L 21/48; H01L 21/56; H01L 23/31; H01L 23/48; H01L 25/18; H10B 80/00; H10D 80/30

(52) U.S. Cl. CPC H10W 20/20; H10W 70/093; H10W 74/01; H10W 74/131; H10W 90/00; H10B 80/00; H10D 80/30; H10W 42/121; H10W 72/0198; H10W 80/312; H10W 80/327; H10W 90/792; H10W 90/794

(57) ABSTRACT

A method for forming a package structure and the package structure formed therefrom are described. The structure includes a first die, a second die, a third die and a filling material. The second and third dies are stacked on and bonded with the first die. The filling material is disposed on the first die and filled between the second and third dies. The first die, the second die and the third die are electrically connected and bonded, sidewalls of the first die are revealed, and at least one sidewall of the second die and at least one sidewall of the third die are revealed.

### BACKGROUND

Packaging technologies involve packing and incorporating different types of stacked semiconductor dies with integrated circuits (ICs) and electronic devices. Reliable processing technology for achieving durable integration and separation are important for wafer level packaging processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic top view of an exemplary packaging component with multiple semiconductor dies in accordance with some embodiments of the present disclosure.

FIGS. 2-7 are schematic cross-sectional views showing various stages of the manufacturing method for forming a semiconductor package structure according to some embodiments of the present disclosure.

FIGS. 8, 9 and 10 are schematic enlarged cross-sectional views showing lateral profiles of the cutting trenches of the stacked structure that was treated with the three-stage cutting process.

FIG. 11 is a schematic cross-sectional view showing an exemplary package structure in accordance with some embodiments of the present disclosure.

FIG. 12 is a flow chart of the process steps of the manufacturing method for forming a semiconductor package structure according to some embodiments of the present disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be appreciated that the following embodiment(s) of the present disclosure provides applicable concepts that can be embodied in a wide variety of specific contexts. The specific embodiment(s) discussed herein is merely illustrative and is related to a three-dimensional (3D) integration structure or assembly, and does not limit the scope of the present disclosure. Embodiments of the present disclosure describe the exemplary manufacturing process of 3D stacking structures and the 3D stacking structures fabricated there-from. Certain embodiments of the present disclosure are related to the 3D stacking structures formed with wafer bonding structures and stacked wafers and/or dies. Other embodiments relate to 3D integration structures or assemblies including post-passivation interconnect (PPI) structures or interposers with other electrically connected components, including wafer-to-wafer assembled structures, die-to wafer assembled structures, package-on-package assembled structures, die-to-die assembled structures, and die-to-substrate assembled structures. The wafers or dies may include one or more types of integrated circuits or electrical components on a bulk semiconductor substrate or a silicon/germanium-on-insulator substrate. The embodiments are intended to provide further explanations but are not used to limit the scope of the present disclosure.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

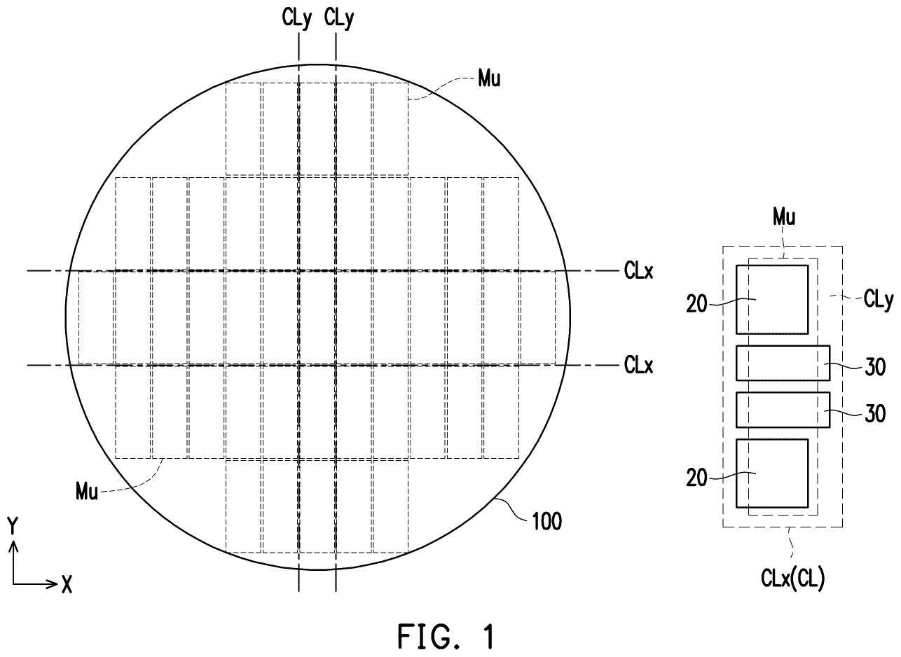

FIG. 1 is a schematic top view of an exemplary packaging component with multiple semiconductor dies in accordance with some embodiments of the present disclosure.

In FIG. 1, a packaging component 100 is provided and may be used to form a stacking structure or a package structure in packaging processes, and a plurality of semiconductor dies 20 and a plurality of semiconductor dies 30 are provided and mounted onto the packaging component 100. In some embodiments, the packaging component 100 is or includes a wafer such as a semiconductor wafer (e.g., a silicon wafer, a germanium wafer or a gallium arsenide wafer) or a reconstructed wafer or a panel board. In some embodiments, the packaging component 100 is a wafer with a plurality of mount units Mu where multiple semiconductor dies 20 and 30 are mounted therein (as seen in the right upper part of FIG. 1), and the mount units Mu are predetermined and defined by reserved cutting lanes CLx (extending in X-direction) and CLy (extending in Y-direction). In some embodiments, the packaging component 100 is a semiconductor bulk wafer with active devices and optional passive devices formed therein. Referring to FIG. 1, the dashed lines represent cutting lanes CLx or CLy by which the packaging component or wafer will be cut in a subsequent cutting or singulation process into the mount units Mu along with semiconductor dies 20 and 30 mounted/bonded thereon. In some embodiments, the semiconductor dies 20 or 30 are the same type of dies and perform the same function. In some embodiments, the semiconductor dies 20 and the semiconductor dies 30 have different designs and perform different functions. As seen in the right upper part of FIG. 1, the span of the semiconductor die(s) 20 or 30 may spread beyond the border of the mount unit Mu and extend into the region of the cutting lane(s) CLy. That is, portions of the semiconductor dies 20/30 are located within the cutting lanes CL (CLx/CLy), and will be trimmed during the cutting process.

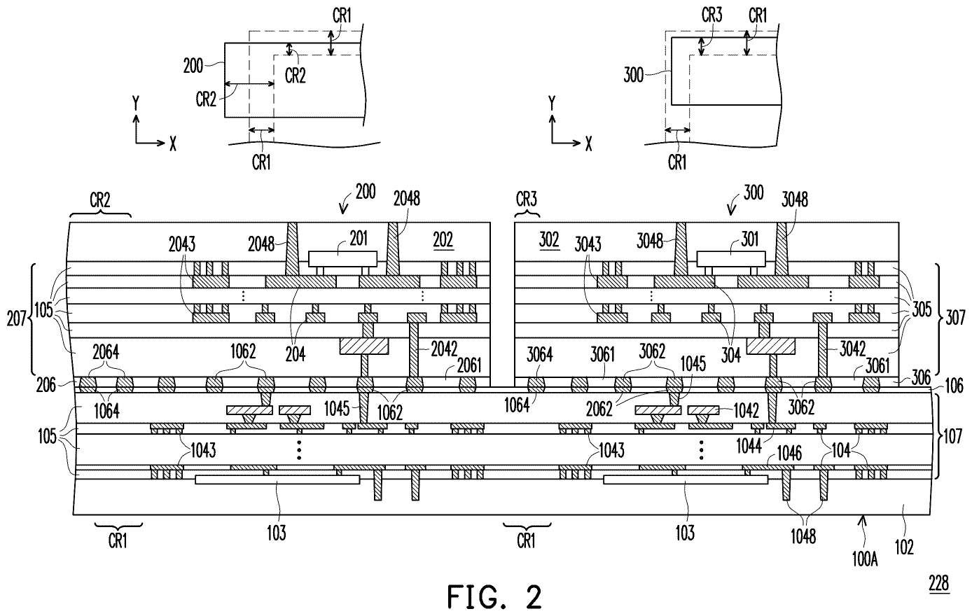

FIGS. 2-7 are schematic cross-sectional views showing various stages of the manufacturing method for forming a semiconductor package structure according to some embodiments of the present disclosure. The same components or elements of similar or the same structure configuration(s) may be labeled with the same reference labels in the drawings. FIG. 2 is a schematic cross-sectional view illustrating an intermediate stacking structure along with exemplary top views illustrating certain portions of the stacking structure at the left upper part and the right upper part of FIG. 2.

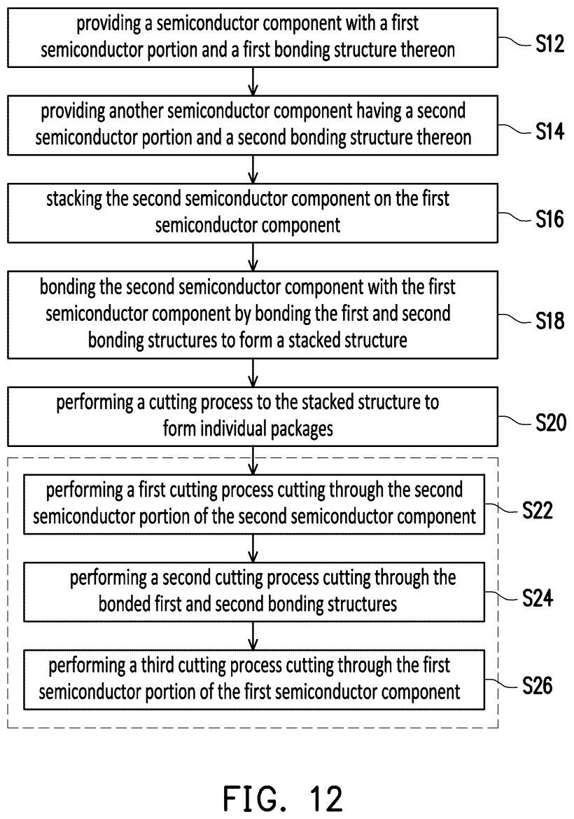

FIG. 12 is a flow chart of the process steps of the manufacturing method for forming a semiconductor package structure according to some embodiments of the present disclosure.

In FIG. 2, in some embodiments, a semiconductor component 100A is provided, and the semiconductor component 100A is similar to the packaging component 100 described in previous paragraphs. In some embodiments, the semiconductor component or wafer 100A is a semiconductor wafer, and the wafer 100A includes a semiconductor substrate 102 with an device layer 103, interconnect structures 107 with metallization structures 104 formed over the semiconductor substrate 102 and the device layer 103, and first bonding structures 106 formed on the interconnect structures 107 and the metallization structures 104 and over the semiconductor substrate 102. Referring to Step S12 of FIG. 12, the semiconductor component 100A is provided with the semiconductor portion (including semiconductor substrate 102) and the first bonding structure 106 thereon. In some embodiments, the wafer 100A is a silicon wafer, or a bulk wafer made of other semiconductor materials such as III-V semiconductor materials such as gallium nitride (GaN) or gallium arsenide (GaAs). In some embodiments, the substrate 102 may be a monocrystalline semiconductor substrate such as a silicon substrate, a silicon-on-insulator (SOI) substrate, silicon-germanium on insulator (SGOI) or a germanium-on-insulator (GOI) substrate. In certain embodiments, the device layer 103 includes semiconductor devices formed in or on the semiconductor substrate 102 of the wafer 100A during the front-end-of-line (FEOL) processes. In certain embodiments, the semiconductor devices are or include transistors, memories or power devices, or other devices such as capacitors, resistors, diodes, photo-diodes, sensors, inductors or fuses. In exemplary embodiments, some of the semiconductor devices may be electrically connected through and with the metallization structures 104. In some embodiments, the wafer 100A may be considered to have a plurality of mount units Mu before cutting or singulation and will be cut into semiconductor dies. In FIG. 2, a portion of the wafer 100A is shown including more than one cut (or diced) units. It is understood that the relative sizes, thicknesses, profiles, directions or angles are merely representative and exemplary but are not intended to limit the scopes of the present disclosure.

As shown in FIG. 2, in certain embodiments, the metallization structures 104 are embedded within an insulation material 105 formed on the semiconductor substrate 102. In some embodiments, the metallization structures 104 include multiple layers of metallization patterns, including interconnected metal lines, vias and contact pads (the detailed configurations and interlayers are omitted and represented by the ellipsis dots). In some embodiments, the metallization structures 104 include electrically floating seal ring structures 1043 located beside and by the cutting lane regions CR1. In some embodiments, the seal rings can reinforce the structural strength and the rigidity of the die unit during later cutting or singulation process. In some embodiments, the metallization structures 104 include contact pads 1042 formed on the top metal lines 1044, bottom metal lines 1046 electrically connected to the device layer 103 and through semiconductor vias (TSVs) 1048 connected to the bottom metal lines 1046. In exemplary embodiments, the semiconductor devices in the device layer 103 are electrically connected with the bottom metal lines 1046 and with the metallization structures 104 and some of the semiconductor devices may be electrically interconnected through the bottom metal lines 1046 and the metallization structures 104. In some embodiments, the metallization structures 104 electrically connect the semiconductor devices of the device layer 103 with the above first bonding structures 106.

As shown in FIG. 2, the first bonding structures 106 are formed over the interconnect structures 107 (on the insulation material 105 and the metallization structures 104). In exemplary embodiments, the first bonding structures 106 include a dielectric material 1061, bonding pads 1062 and dummy bonding pads 1064 embedded in the dielectric material 1061. In some embodiments, the bonding pads 1062 and dummy bonding pads 1064 are metallic pads extending through the dielectric material 1061 and exposed for contacting other metallic bonding pads, so as to provide metallic-to-metallic bonding. In some embodiments, the dielectric material 1061 of the first bonding structures 106 may contact other dielectric material to provide dielectric-to-dielectric bonding. In exemplary embodiments, the first bonding structures 106 function as bonding structures for both of metallic bonding and fusion bonding. In some embodiments, by way of vias 1045, some bonding pads 1062 are electrically connected with the contact pads 1042 or with the top metal lines 1044.

Referring to FIG. 2, in some embodiments, the first bonding structures 106 include bonding pads 1062 that are electrically connected the underneath metallization structures 104 or with other bonding pads of another die or packaging component, and dummy bonding pads 1064 that assist interface bonding but are not electrically functioning. For example, the dummy bonding pads 1064 are arranged in the cutting lane regions CR1 of the wafer 100A and beside where the seal ring structures 1043 are distributed. Using a tetragonal or rectangular cut (or diced) unit as an example, the cutting lanes (represented by the double dashed lines in exemplary top views shown in upper parts of FIG. 2) are set by the four sides of the unit in a ring shape, and some dummy bonding pads 1064 are arranged along the ring-shaped cutting lanes. That is, the dummy bonding pads 1064 in the cutting lane regions CR1 are neither part of the electrical signal path nor part of the power path of the dies or the stacked structure.

In certain embodiments, the materials of the metallization structures 104 include aluminum (Al), aluminum alloys, copper (Cu), copper alloys, titanium (Ti), nickel (Ni), tungsten (W), or combinations thereof. The metallization structures 104 shown herein are merely for illustrative purposes, and the metallization structures 104 may include other configurations and may include one or more through vias and/or damascene structures. In some embodiments, the contact pads 1042 include aluminum pads, the seal rings 1043 are formed from the same processes and are made of the same metal materials for the bottom metal lines 1046, the top metal lines 1044, the vias 1045 and metallic layers formed in-between. In some embodiments, the insulation material 105 includes one or more low-k dielectric sublayers. In some embodiments, the insulation material 105 includes silicon oxide, a spin-on dielectric material, a low-k dielectric material or a combination thereof. In some embodiments, the bonding pads 1062 and the dummy bonding pads 1064 are formed from the same process and are made of the same metallic material. For example, the metallic material includes copper, copper alloys, titanium (Ti), titanium nitride, nickel (Ni), or combinations thereof. In some embodiments, the dielectric material 1061 includes one or more oxide dielectric layers. In some embodiments, the dielectric material 1061 includes silicon oxide, silicon nitride, a spin-on dielectric material such as undoped silicate glass material, a low-k dielectric material or a combination thereof.

As shown in FIG. 2, in exemplary embodiments, there are no electrical functioning contact pads or input/out pads formed in the cutting lane regions CR1, and there are no device layers and/or other electronic components within the cutting lane regions CR1, and such regions or zones CR1 function as sacrificial regions or buffer regions saved for subsequent cutting process(es).

Referring to FIG. 2 and Step S14, in some embodiments, second dies 200 (only one is shown) and third dies 300 (only one is shown) are provided, and in Step S16, the second dies 200 and third dies 300 are stacked onto the wafer 100A. Multiple second dies 200 and multiple third dies 300 are disposed side-by-side on the top surface of the wafer 100A, similar to the semiconductor dies 20 and 30 stacked on the packaging component 100 as seen in FIG. 1. In some embodiments, depending on the product design, more than one second die 200 and more than one third die 300 are mounted onto one mount unit and are included within one cut or (diced) unit. Referring to Step S14, one or more semiconductor components 200 or 300 may be provided with the semiconductor portion(s) (including semiconductor substrate 202/302) and the bonding structure(s) 206/306 thereon.

In certain embodiments, each second die 200 includes a second semiconductor substrate 202, second interconnect structures 207 including second metallization structures 204 embedded in the insulation material 205 formed on the second semiconductor substrate 202, and a second bonding structure 206 formed on the second interconnect structures 207 and connected to the second metallization structures 204 (from top to bottom as the second die 200 faces down in FIG. 2). In embodiments, each second die 200 includes semiconductor devices 201 and isolation structures (not shown) formed in the semiconductor substrate 202. In certain embodiments, the second metallization structures 204 include at least seal rings 2043, through semiconductor vias 2048 and interconnected metal lines and vias 2042 (the detailed configurations and interlayers are omitted and represented by the ellipsis dots). In some embodiments, the second bonding structure 206 includes a dielectric material 2061, bonding pads 2062 that are electrically connected with the second metallization structures 204 and semiconductor devices 201, and dummy bonding pads 2064 that are electrically floating and not electrically connected with the semiconductor devices 201.

In some embodiments, the second die 200 includes a peripheral buffer region CR2 having no active devices or passive devices formed therein but having dummy bonding pads 2064 formed therein. When the second die 200 is stacked onto the wafer 100A, the buffer region CR2 overlaps with the cutting lane regions CR1, and the dummy bonding pads 2064 are bonded with the dummy bonding pads 1064. Depending on the arrangement of the mounted dies, the cutting lane region CR1 may be defined as a ring-shape, and the buffer region CR2 may be in a strip shape, a L-shape or an open ring-shape or C-shape. Referring to the exemplary top view shown at the upper left part of FIG. 2, along the Y-direction extending cutting lane, the buffer region CR2 of the second die 200 is overlapped with the cutting lane region CR1 of the below wafer 100A, and the buffer region CR2 is wider (distance in X-direction) than the cutting lane region CR1. Referring to the exemplary top view shown at the upper left part of FIG. 2, along the X-direction extending cutting lane, the buffer region CR2 of the second die 200 is overlapped with the cutting lane region CR1 of the below wafer 100A, and the buffer region CR2 is narrower (distance in Y-direction) than the cutting lane region CR1.

In certain embodiments, each third die 300 includes a third semiconductor substrate 302, third interconnect structures 307 including third metallization structures 304 embedded in the insulation material 305 formed on the third semiconductor substrate 302, and a third bonding structure 306 formed on the third interconnect structures 307 and connected with the third metallization structures 304 (from top to bottom as the third die 300 faces upside down in FIG. 2). In embodiments, each third die 300 includes semiconductor devices 301 and isolation structures (not shown) formed in the semiconductor substrate 302. In certain embodiments, the third metallization structures 304 include seal rings 3043, through semiconductor vias 3048 and interconnected metal lines and vias 3042 (the detailed configurations and interlayers are omitted and represented by the ellipsis dots). In some embodiments, the third bonding structure 306 includes a dielectric material 3061, bonding pads 3062 that are electrically connected with the third metallization structures 304 and semiconductor devices 301, and dummy bonding pads 3064 that are electrically floating.

In some embodiments, the third dies 300 includes a peripheral buffer region CR3 having no semiconductor devices (active devices or passive devices) formed therein but having dummy bonding pads 3064 formed therein. When the third die 300 is stacked onto the wafer 100A, the buffer region CR3 overlaps with the corresponding cutting lane regions CR1, and the dummy bonding pads 3064 are bonded with the corresponding dummy bonding pads 1064. Depending on the arrangement of the mounted dies, the cutting lane region CR1 may be defined as a ring-shape, and the buffer region CR3 may be in a strip shape, a L-shape or an open ring-shape or C-shape. Referring to the exemplary top view shown at the upper right part of FIG. 2, either along the Y-direction extending cutting lane or along the X-direction extending cutting lane, the buffer region CR3 of the third die 300 is overlapped with the cutting lane region CR1 of the below wafer 100A, and the buffer region CR3 is narrower than the cutting lane region CR1.

In certain embodiments, the materials of the second metallization structures 204 or the third metallization structures 304 may be similar to or the same as that of the first metallization structures 104. In certain embodiments, the materials of the dielectric material and pads of the second bonding structure 206 or the third bonding structure 306 may be similar to or the same as those of the first bonding structures 106. In some embodiments, the peripheral buffer region CR2 or CR3 has no active devices or passive devices formed therein but may have no electrically functional elements.

During the placement of the second dies 200 and the third dies 300, the second dies 200 and the third dies 300 are arranged to align the second bonding structures 206 and the third bonding structures 306 with the corresponding first bonding structures 106 respectively, so that the bonding pads and the dummy bonding pads of respective die(s) are substantially vertically aligned (along the thickness direction) with the bonding pads and dummy bonding pads of the wafer 100A respectively. In some embodiments, once the second dies 200 and the third dies 300 are placed on the wafer 100A, the second bonding structures 206 and the third bonding structures 306 are in direct contact with the corresponding first bonding structures 106. Further, in some embodiments, a bonding process is performed to bond the first, second and third bonding structures 106, 206 and 306 to each other so as to bond the second dies 200 and the third dies 300 with the wafer 100A to form a stacked structure 228 (referring to Step S18). In some embodiments, the bonding process includes performing a low temperature heating process at a temperature of about 100 degrees Celsius to about 200 degrees Celsius to heat and bond the dielectric materials 1061, 2061, 3061 (dielectric-to-dielectric bonding) and then performing a high temperature heating process at a temperature of about 200 degrees Celsius to about 300 degrees Celsius to bond the metallic pads 1062, 1064, 2062, 2064, 3062, 3064 (metallic-to-metallic bonding). In some embodiments, the second dies 200 and the third dies 300 are bonded to the wafer 100A through hybrid interfacial bonding to form a die-stacked-on-wafer structure.

In alternative embodiments, referring to Step S18, another semiconductor component such as a semiconductor wafer or a reconstructed wafer is bonded with the semiconductor component or wafer 100A to form a stacked structure (a wafer-stacked-on-wafer structure).

Referring to FIG. 2, after stacking second dies 200 and third dies 300 onto the wafer 100A, the second bonding structure 206 and the third bonding structure 306 are aligned to and bonded to the first bonding structures 106. There is a bonding interface between the first bonding structures 106 and the second bonding structures 206 and the third bonding structures 306 that are in direct contact with the corresponding first bonding structures. Through the bonding pads 1062, 2062, 3062, the second dies 200 and the third dies 300 are electrically connected with the underlying die units of the wafer 100A.

As seen in FIG. 2, after mounting and bonding, buffer regions CR2 and CR3 are overlapped and partially or fully vertically aligned with the underlying cutting lane regions CR1 respectively, and after bonding, some or all of the bonded dummy bonding pads 1064, 2064, 3064 are located within the cutting lane regions CR1. With the existence of the bonded dummy bonding pads 1064, 2064 and 3064, better interfacial bonding is established. During the subsequently performed three-stage cutting process, less or little cracking or delamination occurs, through the removal of the bonded dummy bonding pads 1064, 2064 and 3064.

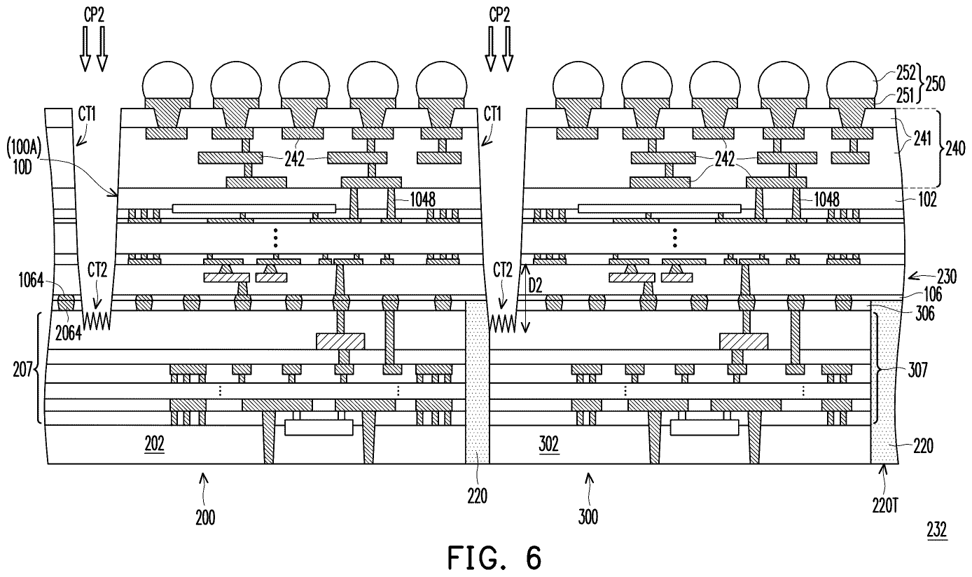

In some embodiments, the area/size of the second die 200 or the third die 300 is smaller than the area/size of one diced unit (cut into the semiconductor dies 10D in FIG. 6) of the wafer 100A, so that portions of the wafer 100A are exposed. For example, the area/size of the second die 200 is larger than or about the same as that of the third die 300. It is understood that the number of the second dies 200 or the third die 300 is merely exemplary.

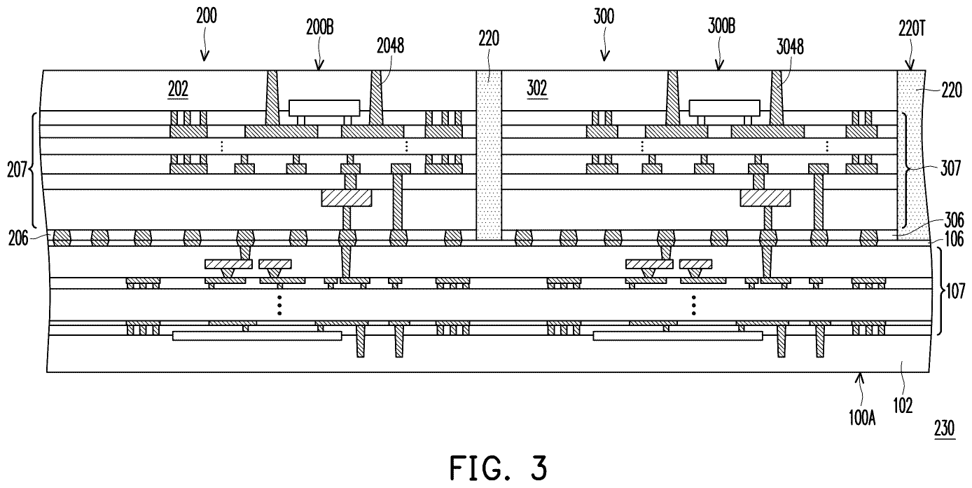

Following FIG. 2 and referring to FIG. 3, a filling material 220 is formed over the die-stacked-on-wafer structure, especially filling the gaps between the second dies 200 and the third dies 300 on the wafer 100A, to form a molded structure 230. In one embodiment, the filling material 220 is formed on the wafer 100A, covering the second dies 200 and the third dies 300, filling up the gaps between the second dies 200 and the third dies 300 and covering the exposed portions of the wafer 100A. In some embodiments, the filling material 220 is an insulating dielectric or polymeric material. In some embodiments, the material of the filling material 220 includes silicon oxide, silicon nitride, epoxy resins, phenolic resins or silicone resins, and optionally filler particles may be included. In embodiments, the filling material 220 is formed by chemical vapor deposition (CVD), spin coating or molding. As seen in FIG. 3, the thickness of the filling material 220 is about the same as that of either the second dies 200 or the third dies 300.

In some embodiments, referring to FIG. 3, the filling material 220 is firstly formed to fully cover the second dies 200 and the third dies 300 bonded to the wafer 100A, and then a planarization process is performed to partially remove the filling material 220. It is understood that the second dies 200 and the third dies 300 may have different thicknesses and such planarization process may partially remove the filling material 220 as well as portions of the second dies 200 and the third dies 300 to form the molded structure 230. The planarization process includes performing a grinding process or a polishing process such as a chemical mechanical polishing process, for example. Referring to FIG. 3, the backsides of the second dies 200 and the third dies 300 are exposed with the ends of the TSVs 2048 and 3048 are exposed. In some embodiments, the filling material 220 at least laterally covers the sidewalls of the second dies 200 and the third dies 300, the top surface 220T of the planarized filling material 220 is levelled with and flush with the backsides 200B of the second dies 200 and the backsides 300B of the third dies 300. Later, the molded structure 230 may be flipped or turned upside down for further processing.

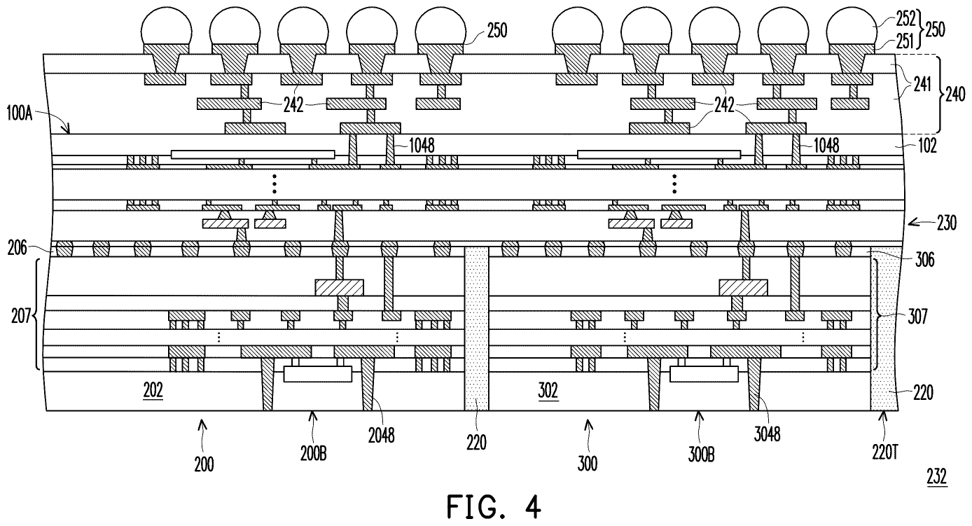

Referring to FIG. 3 and FIG. 4, in some embodiments, another planarization process is performed to the flipped molded structure 230 to partially remove the semiconductor substrate 102 of the wafer 100A. Such planarization process partially removes the semiconductor substrate 102 until the ends of the TSVs 1048 are revealed. The planarization process includes performing a grinding process or a polishing process such as a chemical mechanical polishing (CMP) process, for example. Referring to FIG. 4, the ends of the TSVs 1048 are revealed from the backside surface of the wafer 100A. Later, a redistribution layer (RDL) 240 is formed on the planarized semiconductor substrate 102 of the wafer 100A and over the planarized molded structure to form a stack structure 232. The RDL 240 is electrically connected to the semiconductor devices in the device layer 103 of the wafer 100A through at least the TSVs 1048 and the metallization structures 104.

In some embodiments, the RDL 240 includes redistribution metallic patterns 242 embedded in a dielectric material layer 241. The configuration of the redistribution metal patterns is not limited by the disclosure, while the dielectric material layer may include more than one layers of dielectric materials. The redistribution metallic patterns 242 includes routing metal patterns, vias and metal pads, for example. In certain embodiments, the dielectric material layer 241 exposes some of the underlying redistribution metallic patterns 242, and conductive terminals 250 are formed on the exposed metallic patterns 242. In some embodiments, the conductive terminal 250 includes a metal post 251 and a bump 252. In some embodiments, the material of the dielectric material layer 241 includes silicon oxide, silicon nitride, low-k dielectric materials, benzocyclobutene (BCB), epoxy, polyimide (PI), or polybenzoxazole (PBO). In some embodiments, a material of the metal post 251 includes copper or cooper alloys, and a material of the bump 252 includes solder. In one embodiment, the metal posts 251 and bumps 252 located on the metal posts 251 constitute micro bumps. In some embodiments, the conductive terminals 250 include copper pillar bumps.

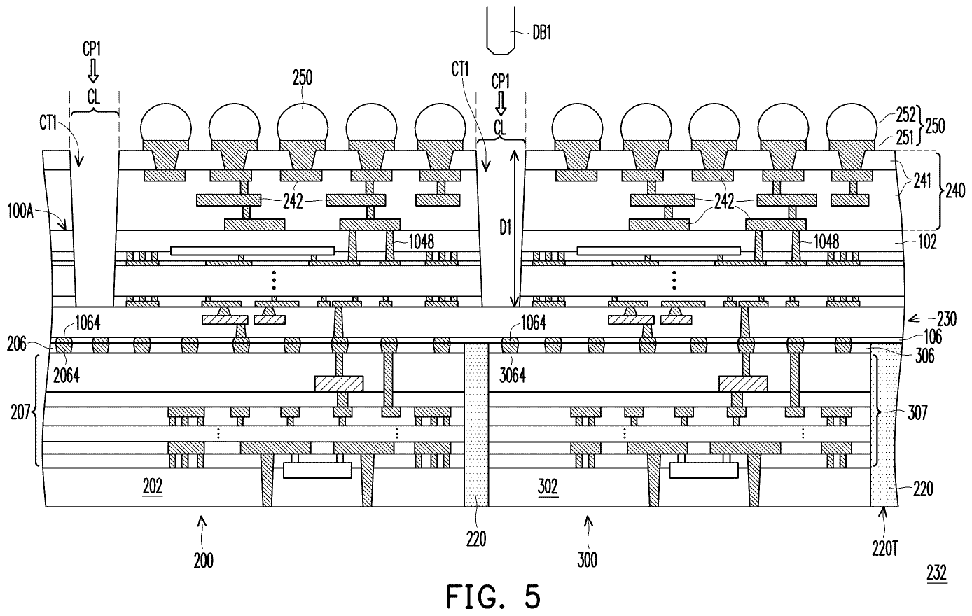

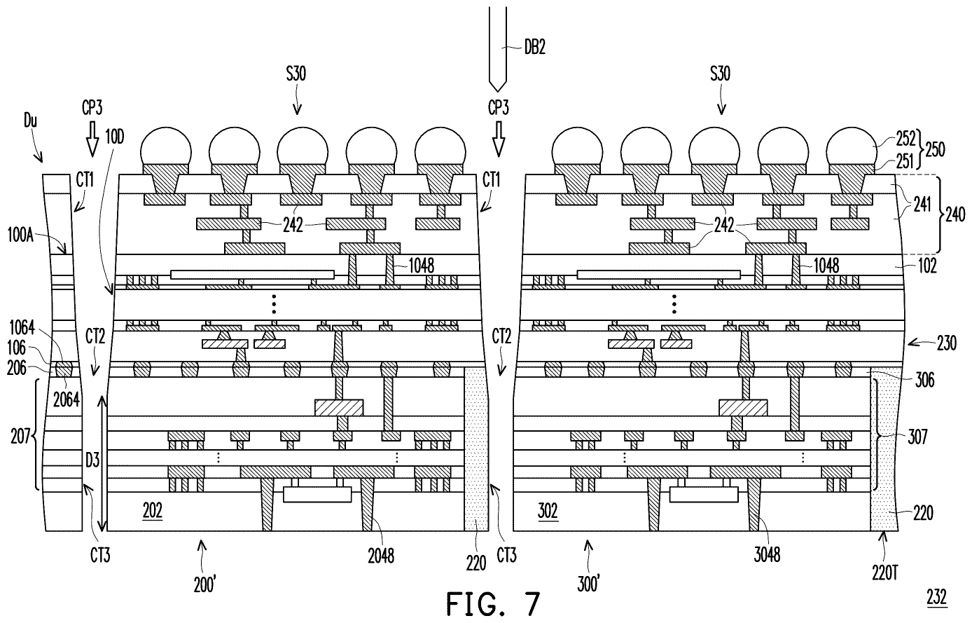

Later, in some embodiments, referring to Step S20 and FIGS. 5, 6 and 7, a three-stage cutting process is performed to cut the stack molded structure 232 along the cutting lanes CL (represented by the dashed lines) into individual three-dimensional (3D) diced structures S30. The diced structures S30 may be referred to as semiconductor components, semiconductor structures, semiconductor dies, or package components. In some embodiments, the three-stage cutting process includes at least performing a first cutting process (in Step S22 and in FIG. 5), performing a second cutting process (in Step S24 and FIG. 6) and performing a third cutting process (in Step S26 and FIG. 7). For example, such three-stage cutting process may be applied as a singulation process or a trimming process for forming the stacked structures, semiconductor dies or package subunits.

Referring to FIG. 5 and Step S22, in some embodiments, the first cutting process CP1 is or includes a mechanical cutting process. The first cutting process CP1 is performed to the stack molded structure 232, cutting from the top surface of the RDL 240, cutting through the RDL 240 and cutting into the wafer 100A to a first depth D1, so that the cutting trench CT1 is formed. Different from the relative dimensions depicted in the figures, the thickness of the semiconductor substrate 102 may be much larger than the total thickness of the RDL 240 or the interconnect structures 107. In some embodiments, the first cutting process CP1 cuts through the RDL 240, and at least cuts through the semiconductor substrate 102, and the first cutting process CP1 optionally cuts into the interconnect structures 107 without cutting through the interconnect structures 107 or the bonding structures 106, to form the cutting trench CT1.

In some embodiments, the first cutting process CP1 includes performing a mechanical sawing or mechanical dicing process using a dicing blade DB1. In some embodiments, the dicing blade DB1 is or includes a kerf blade and/or a blade containing abrasive particles. In one embodiment, the dicing blade DB1 is a kerf blade containing abrasive particles. For example, diamonds are recommended as abrasives for machining hard or difficult-to-cut materials. Depending on the thickness of the blade DB1 and corresponding to the blade profiles, the cutting trench CT1 is formed with slanted or curved and sloped sidewalls. In some embodiments, from the side view, the cutting trench CT1 is formed with an upper width larger than a bottom width, about 25%-50% wider. For example, the cutting depth D1 is in a range of about 40-50 microns, and the bottom width of the cutting trench CT1 is about or larger than 60 microns. Without using high energy sources to generate such as plasma or laser, the first cutting process CP1 adopts the mechanical cutting mechanism and is performed under lower operation temperature(s), and minimal or less metal-silicon residues (silicon recast or recast) are generated when using the first cutting process CP1 cutting through the semiconductor substrate 102.

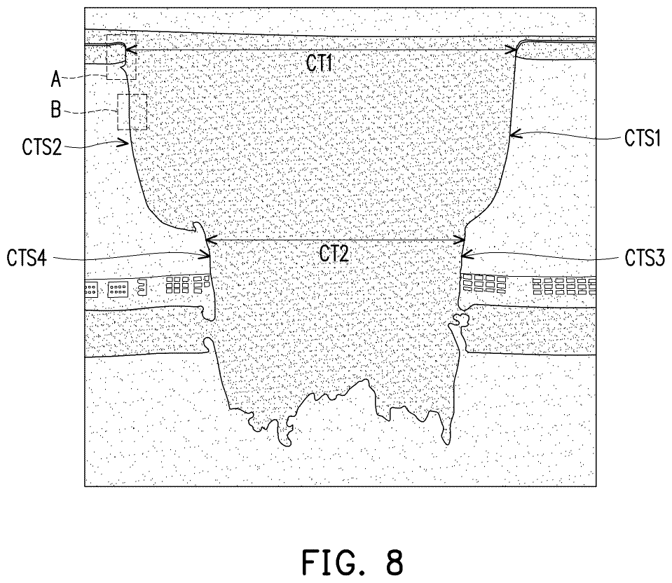

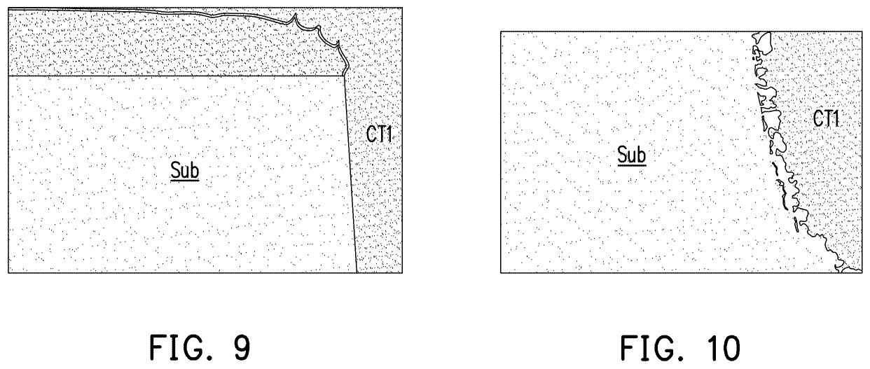

FIGS. 8, 9 and 10 are schematic cross-sectional views showing lateral profiles of the cutting trenches of the stacked structure that was treated with the three-stage cutting process. FIG. 9 is a schematic enlarged cross-sectional view showing the portion A of FIG. 8. FIG. 10 is a schematic enlarged cross-sectional view showing the portion B of FIG. 8.

In some embodiments, from the schematic cross-sectional view of the blade DB1 at the upper part of FIG. 5, the blade DB1 may have beveled surfaces with a truncated end. In some embodiments, the cutting trench CT1 is a bowl-shaped cavity or recess with a curved bottom. Referring to FIG. 8, the cutting trench CT1 is formed with sloped and curved sidewalls CTS1 and CTS2, and the arc curvature of the curved sidewall CTS1 is different from the arc curvature of the curved sidewalls CTS2. Referring to FIG. 9 and FIG. 10, comparing with laser grooving or laser cutting process, the mechanical cutting mechanism and the lower operation temperature(s) of the first cutting process CP1 lead to minimal or nearly no metal-silicon residues (silicon recast or recast) accumulated at the edges or borders of the trench CT1 (as seen in FIG. 9) or less recast (depicted as rough crumbles in FIG. 10) spreading over the sidewalls of the cutting trench CT1, leading to a smoother surface profile (with a reduced surface roughness) of the trench CT1.

By using such mechanical cutting or sawing of the first cutting process CP1 for cutting semiconductor portion (especially silicon portion of the substrate), less recast is formed and the trench sidewalls are endowed with stronger lateral stress, and the cutting trench(es) CT1 will have little or no sidewall crack.

Referring to FIG. 6 and Step S24, following the first cutting process CP1, the second cutting process CP2 is performed to form a cutting trench CT2 right below the cutting trench CT1 and joining with the cutting trench CT1. In some embodiments, the second cutting process CP2 is or includes a laser cutting process, or a laser grooving process. The second cutting process CP2 is performed to the stack molded structure 232, cutting through the remained portion of the wafer 100A and cutting into the below dies (either second die(s) 200 and/or the third die(s) 300) to a second depth D2, so that more than one cutting trench CT2 is formed. Depending on the type of laser and the beam sizes, the cutting trench CT2 is formed with slanted sidewalls. In some embodiments, from the side view, the cutting trench CT2 is formed with an upper width larger than a bottom width, about 5%-15% wider. For example, the cutting depth D2 is in a range of about 40-50 microns, and the total depth of the cutting trenches CT1 and CT2 is about or larger than 90 microns. In some embodiments, the second cutting process CP2 includes performing a laser grooving process with dual narrow laser beams (dual narrow laser grooving). For example, the laser grooving process is performed with narrow beams with a power of about 5 W and a frequency of 500 kHz and a feed speed of about 500 mm/s. In other embodiments, the second cutting process CP2 includes performing a laser grooving process with wide laser beams, narrow laser beams or a combination of wide and narrow laser beams.

In some embodiments, referring to FIG. 6, the second cutting process CP2 cuts through the interconnect structures 107 and the bonding structures 106 as well as the bonding structures 206 or 306 of the respective die(s) 200 or 300, and the second cutting process CP2 optionally cuts into the interconnect structures 207 or 307 of the respective die(s) 200 or 300, to form the cutting trench CT2. In some embodiments, the second cutting process CP2 mainly cuts through the dielectric portion containing metallization patterns, including the interconnect structures 107, 207, 307 and the bonding structures 106, 206, 306. In some embodiments, the second cutting process CP2 removes the dummy bonding pads 1064 within the cutting lane regions CR1, and some of the dummy bonding pads 2064, 3064 located in the buffer regions CR2, CR3. For the dielectric portion containing metallization patterns, the multiple pass of laser beam is able to effectively remove the dielectric material (especially low-k dielectrics) and the metal/metallic patterns therein. By using the laser grooving cutting through mainly the dielectric portion of the stack structure, less heat-affected zones (HAZ) may be generated along the profiles of the joined cutting trenches CT1 and CT2.

Referring to FIG. 8, the cutting trench CT2 is formed with sloped sidewalls CTS3 and CTS4, and the sloped sidewalls CTS3 and CTS4 may have different slopes. In some embodiments, the sloped sidewalls CTS3 and CTS4 may be slightly curved, and the arc curvatures of the sidewalls CTS3 and CTS4 may be different. In some embodiments, as seen from FIG. 8, the bottom of the cutting trench CT2 may be wavy or formed with multiple grooves or channels as narrow beam laser may be used.

Referring to FIG. 7 and Step S26, following the second cutting process CP2, the third cutting process CP3 is performed to form a cutting trench CT3 right below the cutting trench CT2 and joining with the cutting trenches CT2 and CT1. In some embodiments, the third cutting process CP3 is or includes a mechanical cutting process, with a cutting depth D3. Different from the relative dimensions depicted in the figures, the thickness of the semiconductor substrate 202 or 302 may be much thicker than the interconnect structures 207 or 307 and thicker than the semiconductor substrate 102. In some embodiments, the third cutting process CP3 includes performing a mechanical sawing or mechanical dicing process using a dicing blade DB2. In some embodiments, the dicing blade DB2 is or includes a kerf blade and/or a blade containing abrasive particles. In one embodiment, the dicing blade DB2 is a kerf blade containing abrasive particles such as diamond grits. In some embodiments, the mechanical cutting process performed in the first cutting process CP1 is different from the mechanical cutting process performed in the third cutting process CP3, through using different blades and tuning the operational parameters and conditions.

Without using high energy sources to generate such as plasma or laser, the third cutting process CP3 adopts the mechanical cutting mechanism and is performed under lower operation temperature(s), and minimal or less metal-silicon residues (silicon recast or recast) are generated when using the third cutting process CP3 cutting through the semiconductor substrates 202, 302 of the semiconductor dies 200, 300. In some embodiments, the first and third cutting processes CP1, CP3 are performed at operational temperatures lower than an operational temperature of the second cutting process CP2. Depending on the thickness of the blade DB2 and corresponding to the blade profiles, the cutting trench CT3 is formed with almost vertical or slightly sloped sidewalls. In some embodiments, the cutting trench CT3 is formed with substantially upright sidewalls, compared with the sloped sidewalls of the cutting trench CT1 or CT2. In some embodiments, from the side view, the cutting trench CT3 is formed with substantially the same width of about 30-40 microns, and the cutting depth D3 is in a range of about 300-400 microns.

In some embodiments, referring to FIG. 6 and FIG. 7, the third cutting process CP3 is performed to cut through the remaining portion of the stack molded structure 232, cutting through the remained portion of the semiconductor dies 200, 300, especially the semiconductor substrates 202, 302 of the respective second dies 200 and the third dies 300, so as to form trenches CT3. In some embodiments, the third cutting process CP3 trims off portions of the semiconductor dies 200 and 300 to become the trimmed dies 200′ and 300′. Depending on the die arrangements, some of the sidewalls of the trimmed second die(s) 200′ are exposed along with the other sidewalls being covered by the filling material 220, and some of the sidewalls of the trimmed third die(s) 300′ are exposed along with the other sidewalls being covered by the filing material 220.

In some embodiments, through the three-stage cutting process, a portion of the wafer 100A, a portion of the second die(s) 200, a portion of the third die(s) 300, and a portion of the filling material 220 are removed, and by performing such cutting process multiples times, the stack molded structure 232 is singulated into a plurality of individual diced structures S30. In some embodiments, where the cutting lane is partially overlapped with the die span, the singulation process removes a portion of the die. Similarly, the singulation process may remove a portion of the filling material 220 where the cutting lane is overlapped with the filling material.

After performing the cutting process for singulation, each of the singulated 3D diced structures S30 includes at least one second die 200′ and at least one third die 300′ stacked on the semiconductor die 10D and the filling material 220 wrapping around the second die 200′ and the third die 300′. Due to the layout arrangement, from the cross-sectional view shown in FIG. 7, one of the two diced structures S30 is shown to include the trimmed second die 200′, while the other diced structure S30 is shown to include the trimmed third die 300′; however, it is understood that each diced structure (package unit) includes at least one second die 200 and one third die 300.

By performing the third cutting process CP3 and forming the third trench(es) CT3 joined with the trenches CT1 and CT2, the stack molded structure 232 is cut through and singulated to form a plurality of individual diced structures S30. In some embodiments, the third cutting process CP3 mainly cuts through the remaining semiconductor portion of the stack structure, i.e. the semiconductor substrate 202, 302 of the respective die(s) 200 or 300. In some embodiments, a dummy portion Du including a dummy portion (with dummy bonding pad(s) 1064) of the wafer 100A and a dummy portion (with dummy bonding pad(s) 2064) of the second die 200 may be generated through such cutting process, if used as a trimming process to the stack structure. It is possible that the dummy portion or the trimmed portion of the stack structure includes portions of the bottom wafer and the dies 200 and 300.

By using such mechanical cutting or sawing for cutting semiconductor portion (especially silicon portion of the substrate), less recast is formed along the trench sidewalls, and the cutting trenches cause little or no sidewall cracks. Following the singulation using such mechanical cutting or sawing process for cutting the semiconductor portions and using laser process for cutting the dielectric portion(s), recast residues are lessened and the heat-affected zones are minimized, so that the structural rigidity of the obtained components is enhanced. Hence, the singulated components are obtained with stronger bending strengths, and the die bending strength can be increased by about 26%. Through such three-stage cutting process, the fabricated package components or subunits are obtained with stronger bending strength, better reliability and yields during surface mounting (SMT) process and during shipment.

Although the steps of the method are illustrated and described as a series of acts or events, it will be appreciated that the illustrated ordering of such acts or events are not to be interpreted in a limiting sense. In addition, not all illustrated process or steps are required to implement one or more embodiments of the present disclosure. Furthermore, whilst the illustrated processes belong to a chip-on-wafer (CoW) process and may be further fabricated into 3D stacking packages or package structures with subunits stacked on substrate or circuit substrate. In some embodiments, the 3D structures may be fabricated by using a wafer-on-wafer (WoW) process. Furthermore, the 3D stacking structures described above may be further bonded to a circuit substrate or used as package units and fabricated into 3D stacking packages or CoWoS packages, the disclosure is not limited to the package structure shown in the drawings.

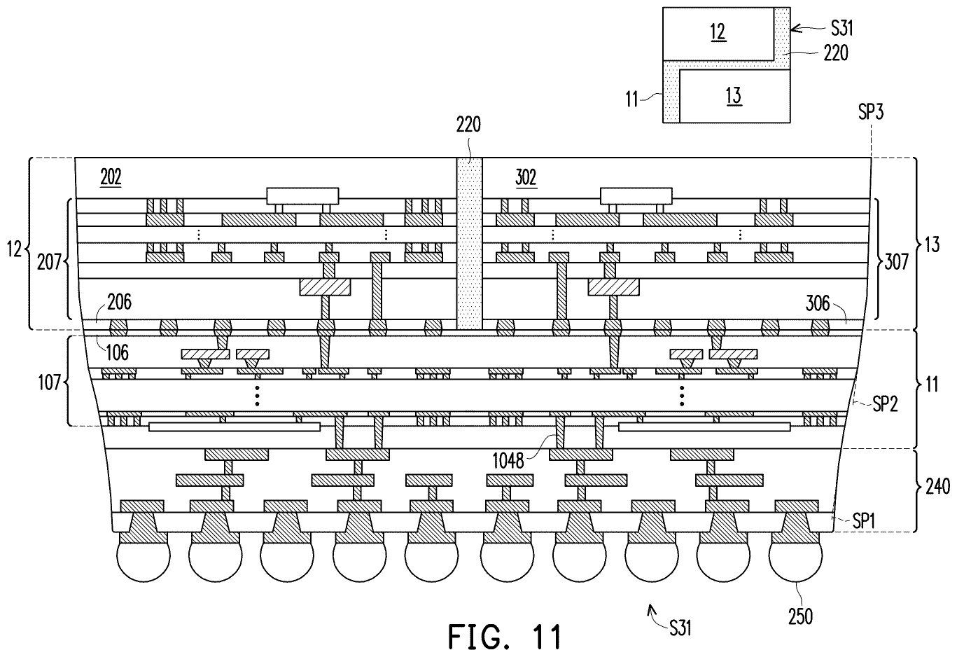

FIG. 11 illustrates a cross-sectional view of an exemplary package structure in accordance with some embodiments of the present disclosure. In exemplary embodiments, in reference to the exemplary arrangement having at least one die 12 and at least one die 13 included within one package unit S31 as shown in upper part of FIG. 11. In the top view at the upper part of FIG. 11, the 3D structure S31 includes the die 11 (as the bottom die) and the dies 12 and 13 disposed on the die 11, and the filling material 220 filled between the dies 12 and 13, wrapping around the dies 12 and 13, and disposed on the bottom die 11. The sidewalls of the bottom die 11 are not covered by the filling material 220 and are revealed. Also, the package unit S31 includes the redistribution layer (RDL) 240 disposed on the bottom surface of the bottom die 11 and conductive terminals 250 disposed on the RDL 240. In some embodiments, the die 11 is similar to the semiconductor die 10D described in the previous paragraphs, and the dies 12 and 13 are similar to the second and third dies 200/200′, 300/300′ described in the previous paragraphs except for having no TSVs. Herein, the same or similar structural features or elements may be labelled with the same reference numbers, and the details and descriptions of the same or similar elements will not be repeated herein for simplification. It is understood that the number of the dies 11, 12, 13 is merely exemplary.

In some embodiments, the dies 11, 12 and 13 have different functions. In some embodiments, the dies 12 or the dies 13 and the semiconductor die 11 have the same functions but are of different sizes. In some embodiments, the die 11 includes a logic die, such as central processing unit (CPU) die, graphic processing unit (GPU) die, micro control unit (MCU) die, baseband (BB) die, or application processor (AP) die. In some embodiments, the dies 12 includes a memory die, such as high bandwidth memory (HBM) die, dynamic random access memory (DRAM) die, or static random access memory (SRAM) die. In some embodiments, the die 13 includes application-specific integrated circuit (ASIC) die, analog die, sensor die, wireless application die (including Bluetooth chips and/or radio frequency chips) or voltage regulator die.

In some embodiments, through the interconnect structures 107, 207, 307 and the bonding structures 106, 206, 306, electrical connection paths are established between the dies 11, 12, 13 of the package unit S31, and further electrical connection paths are established through the TSVs 1048 connected to the RDL 240 and the conductive terminals 250. For example, the conductive terminals 250 may be electrically connected with the die 11 through the RDL 240 and the TSVs 1048 of the die 11 and electrically connected with the dies 12 and 13 through the interconnect structures 107, 207, 307 and the bonding structures 106, 206, 306.

Referring to FIG. 11, in some embodiments, the sidewalls of the bottom die 11 are exposed, the sidewalls of the dies 12 and 13 are exposed, while the facing sidewalls of the dies 12 and 13 are covered by the filling material 220. Taking a rectangular or tetragonal shaped bottom die 11 as an example, four sidewalls of the bottom die 11 are revealed (uncovered by the filling material or any other materials), at least one sidewall of the second die 12 and at least one sidewall of the third die 13 are revealed (at least fully revealed from the filling material 220). Through the previously described three-stage cutting process, the sidewalls of the dies 12 and 13 may be regarded as coplanar with but are not vertically aligned with the sidewalls of the die 11.

In some embodiments, for the singulated package unit S31, due to the three-stage cutting process, the package unit S31 have lateral profiles (sidewall contours) reflecting the cutting profiles of the three-stage cutting process. In some embodiments, the sidewall of the package unit S31 may include a curved and slant surface with a first slope SP1 (resulting from the first cutting process), a slant surface with a second slope SP2 (resulting from the second cutting process) and another slant surface with a third slope SP3 (resulting from the third cutting process), and SP1 is smaller than SP2, and SP2 is smaller than SP3 (SP1<SP2<SP3).

By doing so, cracking or delamination at the edges of the singulated or trimmed stacked structures (or package units) are diminished and the reliability and the production yield are enhanced.

In some embodiments of the present disclosure, a method for forming a package structure is described. A first semiconductor component having a first semiconductor portion and a first bonding structure is provided. A second semiconductor component having a second semiconductor portion and a second bonding structure is provided. The second semiconductor component is stacked on the first semiconductor component. The second semiconductor component is bonded with the first semiconductor component by bonding the first and second bonding structures to form a stacked structure. A cutting process is performed to the stacked structure to form individual packages. The cutting process includes performing a first cutting process cutting through the second semiconductor portion of the second semiconductor component; performing a second cutting process cutting through the bonded first and second bonding structures; and performing a third cutting process cutting through the first semiconductor portion of the first semiconductor component. The first and third cutting processes are performed at operational temperatures lower than an operational temperature of the second cutting process.

In some embodiments of the present disclosure, a method for forming a package structure is described. A first wafer having first dies and cutting lane regions surrounding the first dies is provided. The first wafer includes a first substrate and a first bonding structure formed over the first substrate. Second dies are provided, and the second die includes a second substrate and a second bonding structure formed over the second substrate. The second dies are bonded to the first wafer by bonding the second bonding structures and with the first bonding structure. A filling material is formed on the first wafer and fills between the second dies to form a molded structure. A cutting process is performed to the molded structure. The cutting process includes performing a first cutting process to the molded structure, cutting into the first wafer by cutting through the first substrate; performing a second cutting process after performing the first cutting process, cutting through the bonded first and second bonding structures; and performing a third cutting process after performing the second cutting process, cutting through the second substrates of the second dies. The first cutting process includes performing a mechanical cutting process, the second cutting process includes performing a laser grooving process, and the third cutting process includes performing a mechanical cutting process.

In some embodiments of the present disclosure, a package structure including a first die, a second die, a third die and a filling material is provided. The first die has a first substrate and a first bonding structure located over the first substrate. The second die is stacked on and bonded with the first die. The second die includes a second substrate and a second bonding structure located over the second substrate. The third die is stacked on and bonded with the first die. The third die includes a third substrate and a third bonding structure located over the second substrate. The filling material is disposed on the first die and filled between the second and third dies. The first die, the second die and the third die are electrically connected and bonded through bonding of the first, second and third bonding structures. Sidewalls of the first die are revealed, and at least one sidewall of the second die and at least one sidewall of the third die are revealed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a package, comprising
providing a first semiconductor component having a first semiconductor portion and a first bonding structure;
providing a second semiconductor component having a second semiconductor portion and a second bonding structure;
stacking the second semiconductor component on the first semiconductor component;
bonding the second semiconductor component with the first semiconductor component by bonding the first and second bonding structures to form a stacked structure; and
performing a cutting process to the stacked structure to form individual packages, comprising:
performing a first cutting process cutting through the second semiconductor portion of the second semiconductor component;
performing a second cutting process cutting through the bonded first and second bonding structures; and
performing a third cutting process cutting through the first semiconductor portion of the first semiconductor component,
wherein the first and third cutting processes are performed at operational temperatures lower than an operational temperature of the second cutting process.

2. The method of claim 1, wherein performing the first cutting process includes performing a mechanical cutting process, and performing the second cutting process includes performing a laser grooving process.

3. The method of claim 2, wherein performing a laser grooving process includes using dual narrow beams laser technology.

4. The method of claim 1, wherein performing the first cutting process includes performing a first mechanical cutting process, performing the second cutting process includes performing a laser grooving process, and performing the third cutting process include performing a second mechanical cutting process different from the first mechanical cutting process.

5. The method of claim 1, wherein providing the first semiconductor component includes providing a first semiconductor wafer, and providing the second semiconductor component includes providing a plurality of semiconductor dies.

6. The method of claim 5, further comprising forming a filling material on the first semiconductor wafer and filling between the plurality of semiconductor dies before performing the cutting process.

7. The method of claim 1, wherein bonding the second semiconductor component with the first semiconductor component includes performing a first bonding process at a first temperature and performing a second bonding process at a second temperature higher than the first temperature.

8. The method of claim 1, wherein the first bonding structure includes first dummy pads, the second bonding structure includes second dummy pads, bonding the first and second bonding structures includes bonding the first and second dummy pads, and performing the second cutting process removes the bonded first and second dummy pads.

9. A method for forming a package, comprising:
providing a first wafer having first dies and cutting lane regions surrounding the first dies, wherein the first wafer includes a first substrate and a first bonding structure formed over the first substrate;
providing second dies, wherein the second die includes a second substrate and a second bonding structure formed over the second substrate;
bonding the second dies to the first wafer by bonding the second bonding structures and with the first bonding structure; and
forming a filling material on the first wafer and filling between the second dies to form a molded structure; and
performing a cutting process to the molded structure, wherein the cutting process includes:
performing a first cutting process to the molded structure, cutting into the first wafer by cutting through the first substrate, wherein performing the first cutting process includes performing a mechanical cutting process;
performing a second cutting process after performing the first cutting process, cutting through the bonded first and second bonding structures, wherein performing the second cutting process includes performing a laser grooving process; and
performing a third cutting process after performing the second cutting process, cutting through the second substrates of the second dies, wherein performing the third cutting process includes performing a mechanical cutting process.

10. The method of claim 9, wherein the first bonding structure includes first bonding pads and first dummy pads located in the cutting lane regions, the second bonding structure includes second bonding pads and second dummy pads, and performing the second cutting process removes the first and second dummy pads.

11. The method of claim 10, wherein bonding the second dies with the first wafer by bonding the first and second bonding structures includes forming metallic bonding between the first and second dummy pads and the first and second bonding pads and forming dielectric bonding between dielectric materials of the first and second bonding structures.

12. The method of claim 9, further comprising: providing third dies before forming the filling material, wherein the third die includes a third substrate and a third bonding structure formed over the third substrate, bonding the third dies to the first wafer by bonding the third bonding structures with the first bonding structure, and the molded structure is formed with the filling material filled between the third dies.

13. The method of claim 12, wherein performing the second cutting process cuts through the bonded first and third bonding structures, and performing the third cutting process cuts through the third substrates of the third dies.

14. The method of claim 13, wherein the first bonding structure includes first bonding pads and first dummy pads located in the cutting lane regions, the third bonding structure includes third bonding pads and third dummy pads, and performing the second cutting process removes the first and third dummy pads.

15. The method of claim 14, wherein bonding the third dies with the first wafer by bonding the first and third bonding structures includes forming metallic bonding between the first and third dummy pads and the first and third bonding pads and forming dielectric bonding between dielectric materials of the first and third bonding structures.

16. The method of claim 9, further comprising forming a redistribution layer on the molded structure, and forming conductive terminals on the redistribution layer.

17. A package structure, comprising:
a first die having a first substrate and a first bonding structure located over the first substrate;
a second die stacked on and bonded with the first die, wherein the second die includes a second substrate and a second bonding structure located over the second substrate;
a third die stacked on and bonded with the first die, wherein the third die includes a third substrate and a third bonding structure located over the second substrate; and
a filling material, disposed on the first die and filled between the second and third dies,
wherein the first die, the second die and the third die are electrically connected and bonded through bonding of the first, second and third bonding structures, sidewalls of the first die are revealed, and at least one sidewall of the second die and at least one sidewall of the third die are revealed.

18. The structure of claim 17, wherein the sidewalls of the first die includes a curved and slant surface with a first slope, the at least one sidewall of the second die includes a slant surface with a second slope, and the at least one sidewall of the third die includes another slant surface with a third slope, and the first slope, the second slope and the third slope are different.

19. The structure of claim 17, wherein the first bonding structure includes first bonding pads, the second bonding structure includes second bonding pads, and the third bonding structure includes third bonding pads, the first bonding pads are respectively bonded with the second and third bonding pads, and the first, second and third dies are electrically connected through the bonded first, second and third bonding pads.

20. The structure of claim 17, further comprising a redistribution structure disposed on the first die, and the first die includes through substrate vias connected to the redistribution structure.
